(19) United States
(12) Patent Application Publication
(10) Pub. No.: US 2013/0115433 A1
(43) Pub. Date: May 9, 2013

(54) MICROMECHANICAL SYSTEM

(71) Applicant: National Institute of Advanced Industrial Science and Technology, Tokyo (JP)

(72) Inventors: Kazuma KURIHARA, Tsukuba-shi (JP); Takeshi KOBAYASHI, Tsukuba-shi (JP); Hideki TAKAGI, Tsukuba-shi (JP)

(73) Assignee: National Institute of Advanced Industrial Science and Technology, Tokyo (JP)

(21) Appl. No.: 13/732,655

(22) Filed: Jan. 2, 2013

Related U.S. Application Data
(63) Continuation-in-part of application No. PCT/JP2011/064935, filed on Jun. 29, 2011.

(30) Foreign Application Priority Data
Jul. 2, 2010 (JP) 2010-152425

(51) Int. Cl. B81C 1/00

(52) U.S. Cl. CPC B81C 1/00015
USPC 428/202; 264/259; 264/496; 425/117

(57) ABSTRACT

High precision MEMESs can be manufactured in a large amount without requiring a vacuum process or a lithography process. A film is aligned with a die so as to contact with each other. The film has a functional layer and a releasing layer printed thereon. The die is configured to mold a structure which comprises a functional layer retention part retaining the functional layer and a frame supporting the functional layer retention part. The resin filled between the die and the film is cured. Then, the film is separated from the die so that the functional layer is released from the releasing layer and transferred on the resin cured in the die, thereby the structure is formed.

### CROSS-REFERENCE TO RELATED APPLICATIONS

This application is a continuation-in-part application of PCT application No. PCT/JP2011/064935 under 37 Code of Federal Regulations §1.53(b) and the said PCT application claims the benefit of Japanese Patent Application 2010-152425, filed Jul. 2, 2010, which is hereby incorporated by reference herein in its entirety.

### BACKGROUND OF THE INVENTION

1. Field of the Invention

The present invention relates to a manufacture method for manufacturing a micro-electromechanical system (hereinafter also referred to as “MEMS”) with a low cost and a high efficiency, a die used for the method, manufacture apparatuses used for the method such as a die or a film, and a micromechanical system manufactured by them.

2. Description of the Related Art

Conventionally, the MEMS has been manufactured using a semiconductor manufacturing process such as a film formation apparatus, an exposure apparatus, or an etching apparatus. Atypical manufacturing method of a MEMS device has been carried out, as shown in the following Patent Publications, Japanese Patent Laid-Open No. 2006-332391 and Japanese Patent Publication No. 3588633, by using a semiconductor manufacturing tool to subject a top face or a back face of a wafer (e.g., silicone or silica) to a lithography process to form a pattern of an organic matter or an inorganic matter. Then, the pattern formed on the top face or the back face is etched as a protective layer to thereby form a structure. After these processes for forming the structure are performed a plurality of times, then a process is performed to form an electrode layer functioning as an electric contact or an electrostatic actuator, a piezoelectric layer, a micro coil for example formed by a high-dielectric material layer consisting of a magnetic layer, a thermal deformation layer, or a light-emitting element layer. Then, the MEMS as described above can be combined with the surface of a film of synthetic resin for example to thereby realize a flexible sheet having various functions.

In order to reduce the manufacturing cost, an approach has been employed to use a wafer having an increased diameter so as to maximize the number of MEMS devices that can be manufactured from one wafer. However, the conventional MEMS manufacturing processes require, as described above, many manufacturing processes and manufacturing apparatuses. In particular, the film formation process and the etching process, which must be performed in vacuum atmosphere, causes a very high process cost, thus significantly hindering the manufacturing cost of the MEMS device from being reduced.

### SUMMARY OF THE INVENTION

In view of the above, it is an objective of the present invention to provide a large amount of accurate MEMSs by using, without requiring a vacuum process or a lithography process, a die in which a minute structure is engraved with a less formation process. For example, the objective is to realize the manufacture of an optical MEMS integrated with a lens for example, an energy generation MEMS, or an MEMS used for an acceleration sensor or an inkjet nozzle with a dramatically-reduced manufacturing cost when compared with the conventional manufacturing method.

In order to achieve this objective, the method for manufacturing a micro-electromechanical system according to a first aspect of the present invention, including:
aligning a film with a die so as to contact with each other, the film having a functional layer and a releasing layer printed thereon, the die configured to mold a structure which comprises a functional layer retention part retaining the functional layer and a frame supporting the functional layer retention part;
curing resin filled between the die and the film; and
separating the film from the die so that the functional layer is released from the releasing layer and transferred on the resin cured in the die, thereby the structure is formed.

The resin can be ultraviolet cure resin, thermoset resin, or thermoplastic resin.

The die used for the micro-electromechanical system manufacture method includes:
a first concave section that is filled with resin so as to correspond to the functional layer retention part of the micro-electromechanical system;
a first convex section provided at the outer periphery of the first concave section;
a second concave section that is provided at the outer periphery of the first convex section and that uses filled resin to form a frame of the micro-electromechanical system; a second convex section provided at the outer periphery of the second concave section; and
a third concave section that is provided at the first convex section and that uses filled resin to connect the first concave section to the resin filled in the second concave section.

This die may be configured so that the first convex section and the second convex section have the outer edge and the inner edge having a blade-like shape or the third concave section may have a zigzag-like shape or a plurality of stripes.

Alternatively, a die aggregation may be configured by arranging these dies in lengthwise and crosswise directions. In such case, the second convex section may be adjusted in height so as to form a thin resin layer, and the respective MEMSs may be connected by the thin resin layer and can be ejected from the die aggregation.

The film used for the above method includes a pattern-coating on the functional layer and the releasing layer coated by a screen printing, a relief printing, or a gravure printing.

This film may be configured by being provided as a film obtained by pattern-coating the functional layer via an intermediate layer to the film body or by being provided as a film obtained by etching a semiconductor substrate by the functional layer. Alternatively, a film may be provided by pattern-coating the releasing layer and the adhesive layer onto the film body by a screen printing, a relief printing, or a gravure printing to adhere the functional layer via the adhesive layer to the releasing layer.

The releasing layer may be formed of not only water-repellent resin (e.g., silicone resin) but also an organic film (e.g., resist, acrylic resin, polyester resin) dissolved in solvent (e.g., water, ethanol isopro alcohol, acetone, toluene, ethyl acetate, hexane, methyl chloride ketone) so that the film can be peeled from the die by immersing the entire film in solvent.

The micro-electromechanical system (MEMS) manufactured by the above method includes the functional layer retained by the resin filled in the functional layer retention part. The resin filled in the functional layer retention part is integrally connected to the resin part of the frame supporting the functional layer retention part. In such case, a connecting section between the functional layer retention part and the frame may be formed in an electrode layer of the functional layer. Also, the connecting section of the frame may cause the functional layer retention part to elastically deform at a predetermined stroke to the frame.

According to the method for manufacturing a micro-electromechanical system of the present invention, the vacuum process and many manufacturing processes can be eliminated, thus significantly reducing the MEMS manufacturing cost. Furthermore, in the case of the conventional MEMS manufacturing process using the semiconductor process, the manufacture of a device including the fusion of an optical lens and the MEMS requires many processes. This has caused a disadvantage in which the manufacture of a lens using a semiconductor process finds it very difficult to manufacture an aspheric lens for example.

When the method of the present invention as well as the die and the film are used, by suing a general resin molding using synthetic resin (e.g., a compressive molding, an injection molding, a transfer molding), versatile MEMSs (e.g., an optical MEMS obtained by integrating an optical plane with a MEMS device) can be simultaneously formed only by a molding process.

Therefore, a MEMS device can be provided in front of the illumination such as LED that could not be conventionally used due to a manufacturing cost for example. Thus, the combination of the LED as a point light source with the MEMS mirror can be used for various lighting machineries such as illumination and an automobile headlight for example.

Furthermore, a MEMS device also can be combined with a motion sensor to thereby realize energy-saving lighting by focusing the lighting only on a part generated from a heat source for example. Furthermore, the invention also can be used for a known MEMS device (e.g., an existing power generation MEMS or an acceleration sensor), thus similarly achieving the drastic reduction of the manufacturing cost.

Further features of the present invention will become apparent from the following description of exemplary embodiments (with reference to the attached drawings).

### BRIEF DESCRIPTION OF THE DRAWINGS

FIGS. 1A to 1C illustrate an initial status according to a first embodiment of the method for manufacturing a micro-electromechanical system using ultraviolet cure resin;

FIGS. 2A to 2C illustrate a molten resin filling process of the first embodiment;

FIGS. 3A and 3B illustrate a film contacting process of the first embodiment;

FIGS. 4A to 4C illustrate a film separating process of the first embodiment;

FIGS. 5A to 5D illustrate a cured resin ejecting process of the first embodiment;

FIGS. 6A and 6B illustrate an example of the MEMS completed by the processes of the first embodiment;

FIG. 7A illustrates an initial status according to a second embodiment of the method for manufacturing a micro-electromechanical system using thermoplastic resin;

FIG. 7B illustrates a film insertion process of the second embodiment;

FIG. 7C illustrates a die clamping process of the second embodiment;

FIG. 7D illustrates a molten resin filling process of the second embodiment;

FIG. 7E illustrates a die opening process of the second embodiment;

FIG. 7F illustrates a MEMS separating process of the second embodiment;

FIG. 8 illustrates an example of the MEMS connected only by a one-side connecting section;

FIG. 9 illustrates an example of the MEMS connected only by a one-side zigzag-shaped connecting section; and

FIG. 10 illustrates an actual manufactured example of a MEMS device.

### DESCRIPTION OF THE EMBODIMENTS

Hereinafter, an embodiment of the present invention will be described with reference to the drawings.

### [First Embodiment] (Case Where Ultraviolet Cure Resin is Used)

In the present embodiment, a case will be described in which a MEMS structure is configured so that a resin frame includes therein a supported functional layer composed of an electrode layer, a piezoelectric layer, or a high-dielectric material layer for example and a space is provided. The space allows, during a voltage application, the functional layer supported by the resin frame to move.

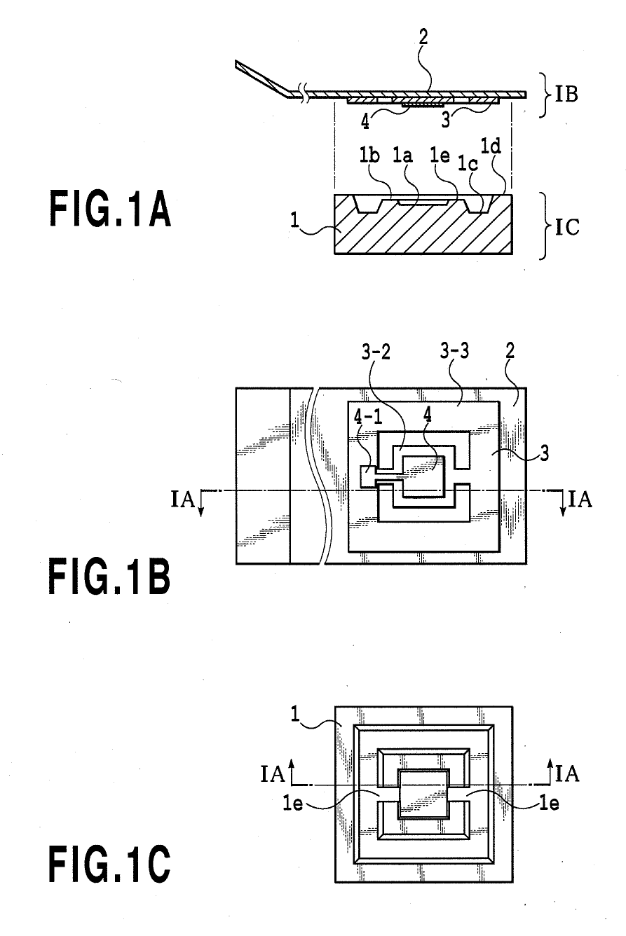

This MEMS element is configured so that the electrode layer at both left and right ends are casted into the interior of the resin part supporting the functional layer and the remaining resin at the periphery of the piezoelectric layers is removed to thereby achieve the operation of the piezoelectric element. FIGS. 1A to 6B illustrate the MEMS manufacturing processes according to the present embodiment.

(1) Transfer of a Film and a Functional Layer

As shown in FIGS. 1A to 1C, a film 2 is formed by ultraviolet light-transmissive resin (e.g., PET, PEN, polycarbonate, polyimide, and acrylic). The film 2 has a releasing layer 3 to correspond to a MEMS functional layer 4 and a frame for supporting this.

In the present embodiment, the functional layer 4 includes layers (e.g., an electrode layer 4-1, a piezoelectric layer, and a high-dielectric material layer) and is formed under the releasing layer 3 via an intermediate layer (not shown).

The releasing layer 3 is composed of an inner small substantially-square part 3-2 that corresponds to the piezoelectric layer or the high-dielectric material layer for example in the functional layer 4 and an outer substantially-square frame section 3-3 corresponding to a resin frame. The inner small substantially-square part 3-2 and the substantially-square frame section 3-3 form a connecting section in the functional layer 4 that connects the electrode layer 4-1 and the corresponding part opposed thereto. Specifically, in the embodiment, the releasing layer 3 includes, except for the upper and lower U-shaped parts, a part corresponding to the functional layer 4, the part 3-3 corresponding to the outer resin frame, the left part of the connecting section corresponding to the electrode layer 4-1, and the right part of the connecting section opposed to this in the horizontal direction.

The releasing layer 3, the functional layer 4 and the intermediate layer are formed by coating a pattern on the film 2 using a screen printing, a relief printing, a gravure printing or the like.

The functional layer 4 is formed by coating conductive ink, piezoelectric material, or dielectric material so as to form a pattern. The intermediate layer functions to strengthen coupling between the releasing layer 3 and the functional layer 4 and thus is not required if the coupling therebetween is strong.

The functional layer 4 can be formed on a pattern-protected film top surface by using a vacuum apparatus (e.g., a sputtering apparatus, an evaporation apparatus). Also, it can be formed by coating and shaping a conventional functional layer on the surface of the film 2. Alternatively, by etching a semiconductor substrate of silicon, SiO₂ or the like, a large amount of the functional layers may be formed in advance and these functional layers may be adhered to the surface of the releasing layer 3 at a predetermined position of the film 2 via an adhesive layer for example. This adhesive layer is also coated on the releasing layer 3 so as to form a pattern using a screen printing, a relief printing, a gravure printing and the like.

The releasing layer 3 is formed of for example water-repellent resin (e.g., silicone resin) and functions to provide a smooth separation even when molten resin which is closely contacted with the layer 3 cures. The releasing layer 3 may be formed by any resin or inorganic matter so long as the resin or inorganic matter shows a water-repellent property when the contact angle is measured by pure water.

(2) Die 1

The die 1 is used to form a structure including a motion space for allowing, for example, the piezoelectric layer of the functional layer 4 to realize the piezoelectric element function. In the present embodiment, as shown in FIGS. 1A to 1C, the center part of the functional layer 4 that corresponds to the layer (e.g., the piezoelectric layer, the high-dielectric material layer) has the first concave section 1a. The outer periphery thereof has the first convex section 1b that is used to form a thin layer to surround the functional layer 7 while excluding resin. The first convex section 1b has, at the outer periphery thereof, the second concave section 1c used for form a frame for retaining the functional element 4 by resin. The outer periphery thereof has the second convex section 1d used to separate MEMS while excluding resin. The first convex section 1b has a part corresponding to the electrode layer 4-1 of the functional layer 4 and a part opposed to this has the third concave section 1e having a narrow width. This concave section 1e functions to connect the first concave section 1a of the center part corresponding to the layer (e.g., a piezoelectric layer, a high-dielectric material layer) to the second concave section 1c for forming a frame. When a point light source LED is employed as the functional layer 4, the resin for retaining the LED can have a lens-like shape by allowing the first concave section 1a to have a concave surface.

The die can be formed by a silicon substrate, stainless, silicone carbide, glassy carbon, glass or nickel, iron, aluminum, dielectric material such as silicon nitride or the like. The die can be manufactured by using machining or semiconductor processings.

(3) Molten Resin Injection

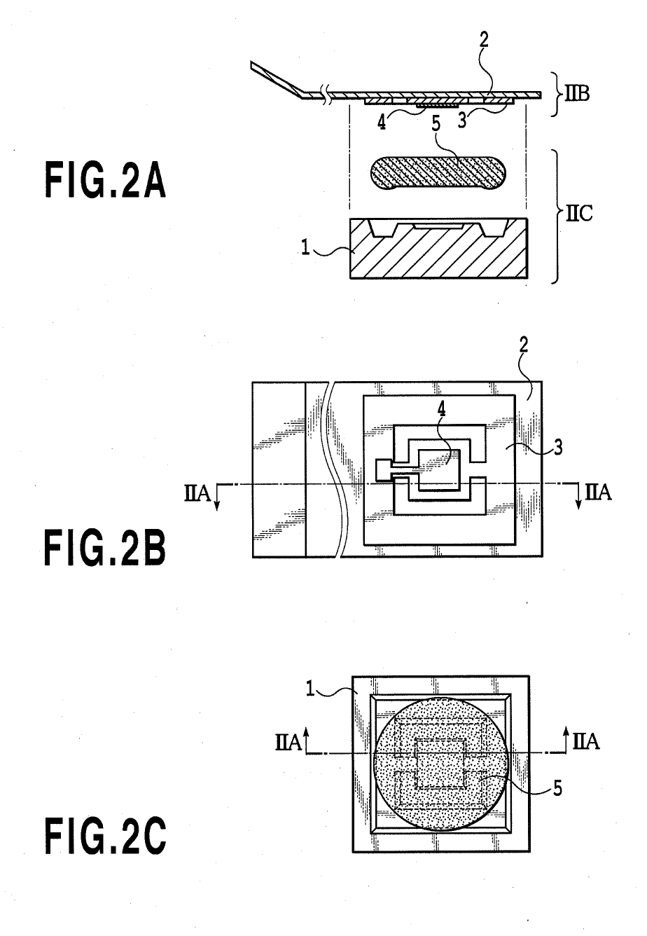

As shown in FIGS. 2A to 2C, a predetermined amount of the molten ultraviolet cure resin 5 is injected to the center part of the die 1 having the structure as described above.

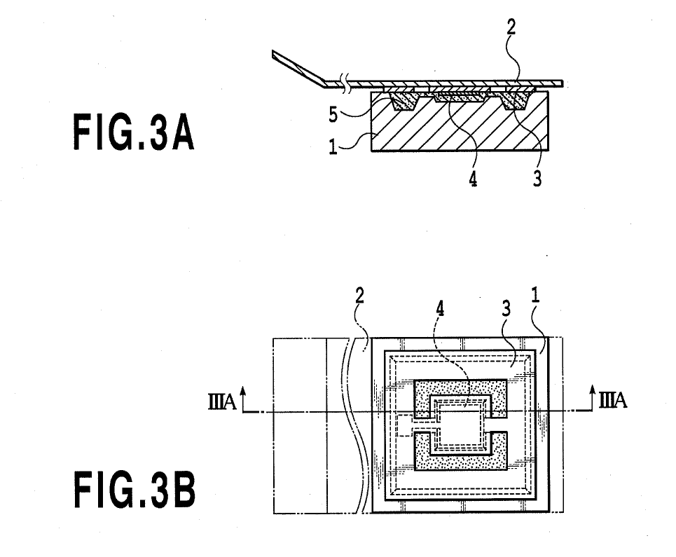

The die 1 and the film 2 have thereon alignment markers. By superposing these marks as shown in FIGS. 3A and 3B, an alignment between the die 1 and the film 2 is made and the film 2 is pressed so as to closely contact to the thermoplastic resin 5.

(4) Separation of Film 2

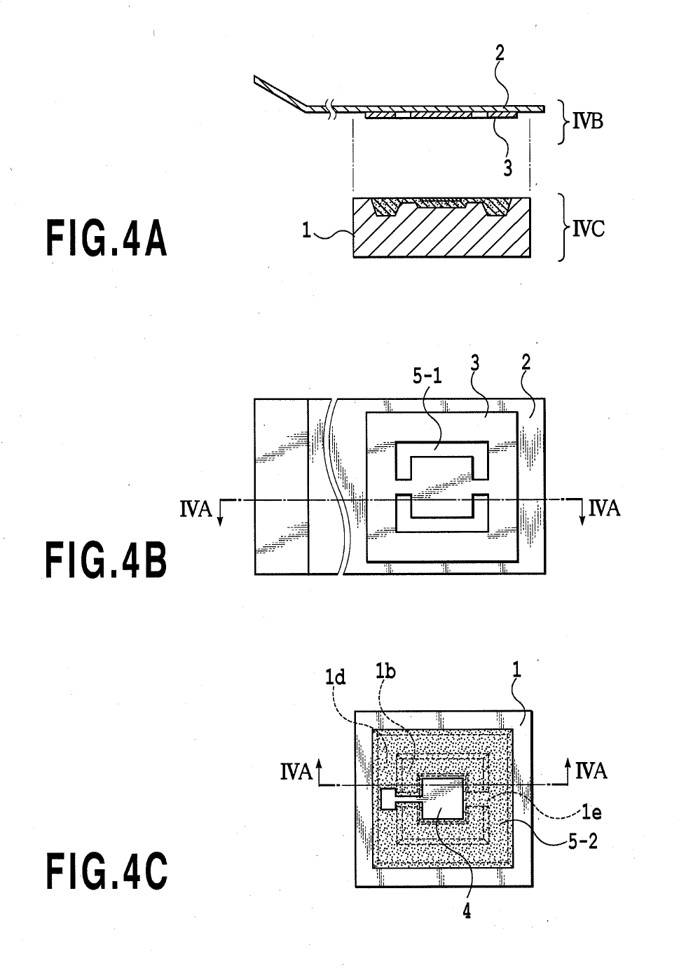

Next, as shown in FIGS. 4A to 4C, after the alignment and the contacting between the die 1 and the film 2, ultraviolet light is emitted from above the film 2. The ultraviolet light passing through the film 2 is used to cure the ultraviolet cure resin 5 after which the film 2 is separated.

During the separation, the cured resin 5-2 at the lower side of the releasing layer 3 is easily released and remains in the die 1 while retaining the functional layer 4. However, the parts corresponding to the upper and lower U-like parts 5-1 and the part corresponding to the outer periphery-side convex section 1d do not have the releasing layer 3. Furthermore, the convex sections 1b and 1d of the die 1 extrude the ultraviolet cure resin 5 to provide a very-thin layer. Thus, the very-thin layer and the film 2 are released while the very-thin layer is strongly adhered to the film 2.

During this, as described above, the center concave section 1a and the concave section 1c for forming a frame are connected by the concave section 1e having a narrow width provided to correspond to the electrode layer 4-1 of the functional layer 4 and a part opposed to this. This part also has the releasing layer 3. Thus, the resin filled in the center concave section 1a and the resin filled in the concave section 1c remain in the die 1 while being connected and supported by the resin filled in the concave section 1e. The resin 5-1 of the upper and lower U-like parts not having the releasing layer 3 is separated together with the film 2.

For the alignment of the film 2, when the tip ends of the inner edge and the outer edge of the respective convex sections 1b and 1d of the die 1 are formed to have a blade-like shape so as to correspond to the inner edge and the outer edge of the releasing layer 3 of the film 2, the boundary between the resin separated together with the film and the resin remaining on the die 1-side can have a blade-like shape concave section and thus the separation therebetween can be performed more securely, thus realizing the manufacture of a smaller MEMS.

(5) Ejection from Die 1

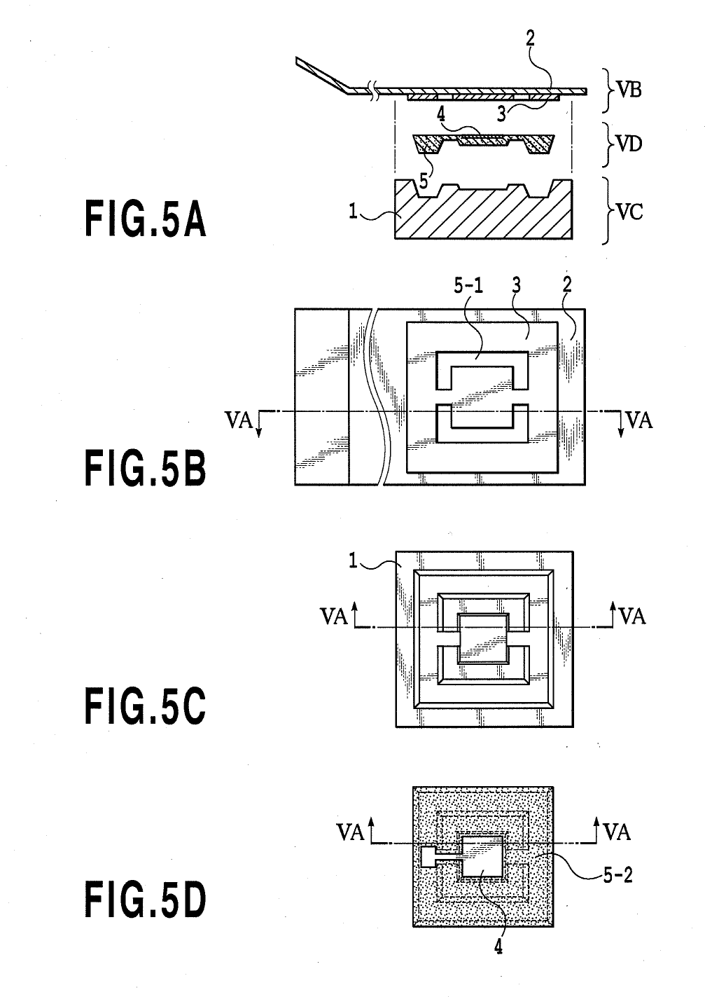

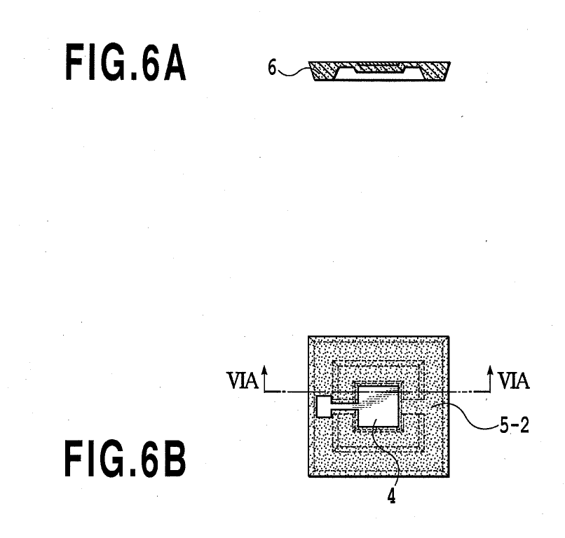

As shown in FIGS. 5A to 5D, a typical eject pin (not shown) used for the injection molding is used to cast the remaining functional layer 4 to remove the cured resin. Then, as shown in FIGS. 6A and 6B, a thin resin layer formed between the concave section 1a of the center part of the die 1 and a part of the functional layer 4 corresponding to a layer (e.g., a piezoelectric layer, a high-dielectric material layer) and the resin part filled in the concave section 1c at the outer periphery side of the die 1 are connected by the resin remaining between the electrode layer 4-1 of the functional layer 4 and the concave section 1e provided at a position opposed to this, thereby completing the MEMS.

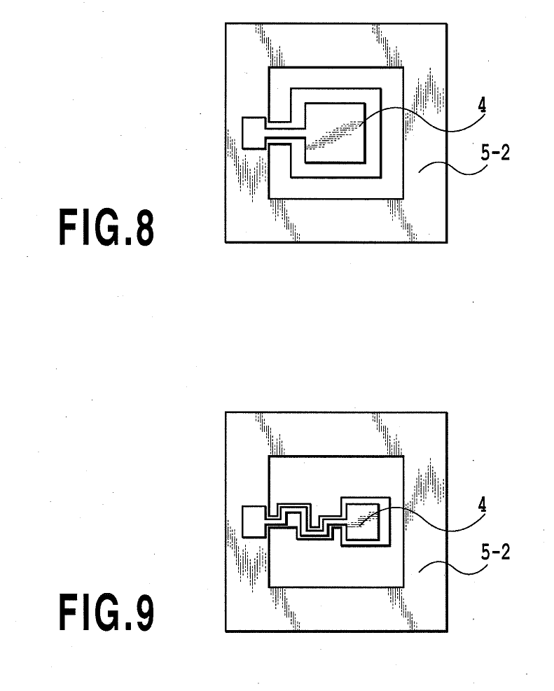

In the present embodiment, the two opposed convex sections 1b were used to connect a part corresponding to the piezoelectric layer or the high-dielectric material layer for example to the frame by the resin filled in the concave section 1c. However, another configuration also may be used depending on the MEMS function for example as shown in FIG. 8 in which only one of them is connected to the frame. Alternatively, the concave section 1e may have a zigzag-like shape when seen from the top as shown in FIG. 9. Alternatively, the connection may be achieved by a plurality of narrow stripe-like connecting section to provide a structure having an elastical (spring) deformation at a predetermined stroke so that the horizontal elasticity can be given to the part corresponding to a layer (e.g., a piezoelectric layer, a high-dielectric material layer). When elasticity is given in a vertical direction, a zigzag-like shape when seen from the side may be used or a plurality of stripe-like connecting sections may be connected.

In an actual manufacturing process, a plurality of dies 1 are arranged in lengthwise and crosswise directions to form a die aggregation. The releasing layer 3, the functional layer 4 and the like are coated in lengthwise and crosswise directions so as to form a pattern on a film having the same shape and size as those of this die aggregation, correspondingly to the respective dies 1. Then, the front face of the die aggregation is coated with the ultraviolet cure resin 5 using a roller or the like. In addition, the film 2 is positioned with respect to the die aggregation. Well-known vacuuming for example is used to provide a close contact between the film 2 and the die aggregation while preventing bubbles from being mixed, thereby forming many MEMS elements simultaneously. The die aggregations may be formed in the lengthwise and crosswise directions by subjecting a flat plate of the above-described die material to a machining process or a semiconductor processing process to form many dies 1 in the lengthwise and crosswise directions. The single die 1 forms a single element in the die aggregation. Alternatively, many dies arranged in the in lengthwise and crosswise directions may be integrated to have a flat panel-like shape by heat-resistant and durable resin such as carbon fiber reinforced plastic.

In this case, the convex section 1d of each die 1 may have an adjusted height and the thin resin layer of this part connects the respective MEMSs so that the respective MEMSs can be removed from the die aggregation. Thus, the respective MEMSs can be separated at a stage for manufacturing the apparatus using MEMS. In order to achieve an easy separation of the connecting sections of the respective MEMSs, blade-like shape projections may be provided so as to form a separation line at the boundary of the convex sections 1d of the respective connected dies 1.

In the present embodiment, the film 2 was formed by ultraviolet light-transmissive resin and the ultraviolet light was emitted through the film 2. However, when the die 1 is formed by ultraviolet light-transmissive material such as glass, ultraviolet light-transmissive material maybe emitted via the die 1 to cure the ultraviolet cure resin 5.

### Second Embodiment

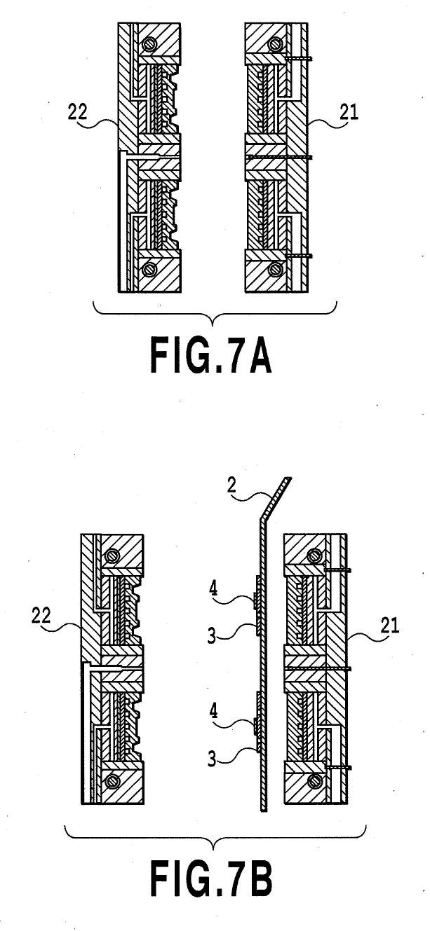

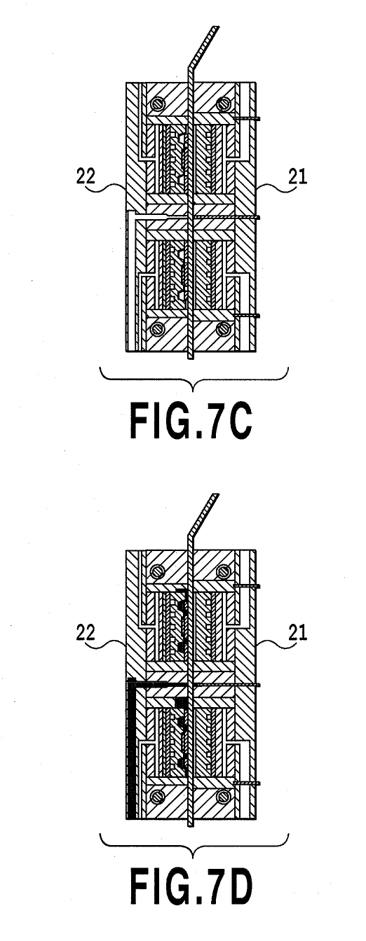

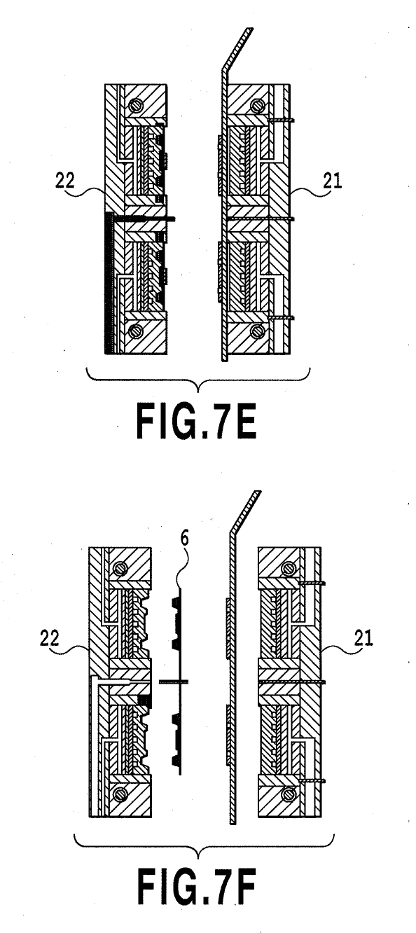

In the first embodiment, ultraviolet cure resin was used. However, in this embodiment, an example as shown in FIGS. 7A to 7F is shown in which the MEMS is manufactured by subjecting thermoplastic resin to an injection molding.

The second embodiment is common to the first embodiment in that the die 1, the film 2, as well as the functional layer 4, the intermediate layer, and the releasing layer 3 printed and formed on the film 2 have the same configurations as those of the first embodiment.

As shown in FIG. 7A, the die 1 having two stages is set on a stationary injection molding die 22. Then, as shown in FIG. 7B, the film 2 on which the functional layer 4, the intermediate layer, the releasing layer 3 or the like are printed is sent. A well-known image sensor (not shown) for example is used to achieve a precise alignment between the marker of the die 1 and the marker of the film. Then, a movable injection molding die 21 is driven as shown in FIG. 7C to perform die clamping.

Next, as shown in FIG. 7D, molten thermoplastic resin is injected at a high speed through the resin injection opening of the stationary injection molding die 22 to fill a thin layer formed by the concave sections 1a and 1c as well as the convex section 1d of the die 1.

When the molten thermoplastic resin is cooled and cured, the mold opening is performed as shown in FIG. 7E. Thereafter, as shown in FIG. 7F, the MEMS is separated from the die 1 using an eject pin or the like, and the film 2 is fed. By repeating the above-described process, the MEMS can be manufactured at a very high efficiency.

### OTHER APPLICATION EXAMPLES

In the first and second embodiments, an example has been shown in which ultraviolet cure resin and thermoplastic resin were used as resin. However, thermosetting resin also may be used. In this case, a transfer molding for example maybe used by using the same procedure as that of the first embodiment to inject molten thermosetting resin into the die 1 to heat, instead of ultraviolet light illumination, the resin by a heater provided in the die 1. In this case, the die 1 must be made of such material that has a high thermal conductivity (e.g., stainless). When thermosetting resin is used, the resin can be sent through a reflow process, thus providing an advantage of the integration with a semiconductor element.

Furthermore, the functional layer 4 can have different configuration and pattern depending on a MEMS element to be manufactured and can have various functions.

For example, in the case of a MEMS actuator element by an electrostatic force, the only required element is an electrode layer. Thus, a MEMS element can be prepared by using a film obtained by constituting an electrode layer on the top face of a releasing layer.

In the case of a MEMS actuator using a piezoelectric element or a power generation element, a MEMS element having the minimum required configuration can be prepared by using a film obtained by forming an electrode layer/piezoelectric layer/electrode layer on the top face of a releasing layer.

In the case of a MEMS actuator using a magnetic force, such a film may be used that has an electrode layer and a magnetic layer on the top face of the releasing layer. In the case of a MEMS actuator to be deformed by heat generation, such a film may be used that has an electrode layer and a heat generation layer on the top face of the releasing layer.

The electrode layer may be made of PEDOT, conductive ink, a thin metal film for example.

The piezoelectric layer may be made of polyvinylidene fluoride (PVDF), PZT, phase-change material, crystal (SiO₂), zinc oxide (ZnO), Rochelle salt (KNaC₄H₄O₆), lithium titanate (LiNbO₃), lithium tantalate (LiTaO₃), lithium tetraborate (Li₂B₄O₇), langasite (La₃Ga₅SiO₁₄), aluminum nitride, or tourmaline for example.

The filling resin used in the molding step includes various resins such as ultraviolet light cured resin, thermoplastic resin, or thermoset resin (e.g., epoxy resin, acrylic, polycarbonate, ZEONOR, ZEONEX, nylon).

The MEMS structure also can be formed by curing metal. The molding step can be performed by various molding methods including heat imprinting, UV imprinting, injection molding, transfer molding, or press molding.

Alternatively, a water-repellent resin (e.g., silicone resin) was used for the demolding film in order to promote the physical peeling of the cured ultraviolet cure resin due to ultraviolet light passing through the film 2. However, the invention is not limited to this. Another resin also may be used that is selectively molten to specific solvent.

Specifically, in Embodiment 1, in order to correspond to the MEMS functional layer 4 including the electrode layer 4-1 and a layer (e.g., a piezoelectric layer, a high-dielectric material layer) and a frame for supporting this part, the releasing layer 3 is formed by using an organic film (e.g., resist, acrylic, polyester resin) to emit, after the completion of the alignment of the die 1 and the film 2 and the pressure-bonding therebetween, ultraviolet light from above the film 2 to use ultraviolet light having passed through the film 2 to cure the ultraviolet cure resin 5 to subsequently release the film 2 by immersing the entire die 1 including the functional layer 4 and the frame for supporting this part into organic film solution (e.g., resist, acrylic resin, polyester resin) dissolved in solvent (e.g., water, ethanol isopro alcohol, acetone, toluene, ethyl acetate, hexane, methyl chloride ketone). This solution enters a gap between the die 1 and the film 2 and has no influence on the functional layer 4 and the electrode layer 4-1 and the ultraviolet cure resin 5. This solution selectively causes resist only the releasing layer 3 formed by resin (e.g., acrylic resin, polyester resin) to be selectively molten without applying a physical releasing force to the film 2. Thus, the functional layer 4 and the electrode layer 4-1 can be prevented from receiving a physical impact and the film 2 can be released from the die 1 very smoothly.

### Actual Manufacture Example 1

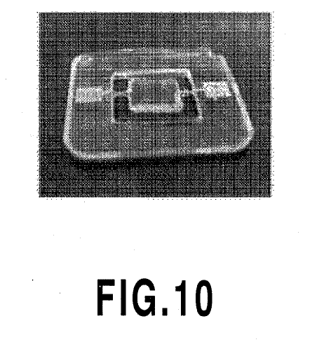

FIG. 10 shows a photograph of a MEMS structure prepared by the method of the present invention. In this manufacture example, the MEMS was manufactured based on the following procedure.
(1) A die was prepared by cutting stainless (Starbucks). The die was machined so as to have a MEMS structure shape. Then, a releasing film was coated on the die surface to prepare a molding die.
(2) A film given with a functional film was prepared by coating the surface of a PET film with silicone resin made by Dow Corning Toray Co., Ltd. as a releasing layer.
(3) Next, on a region of the coated silicone resin surface, conductive ink made by TOYO INK CO., LTD. was coated on a region to be transferred onto the molding product.
(4) In order to mold the functional film-attached film and the molding die, a film was placed that was filled with UV resin (PAK-02 made by Toyo Gosei CO. Ltd.) and that had a functional film printed in advance on the top face. Then, ultraviolet light was emitted to the film while compressing the film, thereby curing the UV resin.
(5) After curing, the film was demolded from a molding die. During this demolding step, a pattern of an adhesion layer and a releasing layer coated on the film was used to leave the MEMS molding resin (hollow part) on the film and to transfer the electrode layer coated on the film onto the MEMS structure molding product. As can be seen from the photograph of FIG. 15, the MEMS structure can be machined into a die to mold the die to thereby manufacture a MEMS membrane structure having a different thickness.

### Actual Manufacture Example 2

In this manufacture example, a MEMS was manufactured based on the following procedure.
(1) A die was prepared by cutting stainless (Starbucks). The die was machined to have a MEMS structure shape. Then, a demolding film was coated on the die surface to prepare a molding die.
(2) A Teijin Tetoron film made by Teijin DuPont Films Japan Limited was used as a PET film. LTC310 made by Dow Corning Toray Co., Ltd. was used as a releasing layer. Then, LTC310 and pure toluene were dissolved at a ratio therebetween of 2:1. Then, addition curing type catalyst SR212 similarly made by Dow Corning Toray Co., Ltd. of 0.5 wt % was added to the resultant mixture to perform coupling. Then, a screen printing apparatus was used to partially print and coat a silicone layer to heat the layer at 100 degrees C. on a hot plate for 30 seconds to fix the layer.
(3) Next, on the coated silicone resin surface, a region that must be transferred to the molding product was coated with a conductive film of silver paste FA301A (made by Fujikura Ltd.). The temperature from 80 degrees C. to 120 degrees C. is preferably maintained in order to promote the silver paste coating.
(4) A functional layer was prepared by dissolving PVDF having a piezoelectric characteristic of 20 wt % in solvent of MEK (methyl ethyl ketone) of 80 wt % at 100 degrees C. Then, a coater was used to coat the resultant solution with a gap of 0.05 millimeters.
(5) Next, in order to electrically connect the conductive layer formed in the (3) to the PDVF functional layer formed in the (4), the silver paste FA201A made by made by Fujikura Ltd. was similarly used as in the (3) to form a conductive layer.

The subsequent steps are the same as those of the (4) and (5) of (actual manufacture example 1).

According to the investigation result of the characteristics of the MEMS structure formed in the manner as described above, a hysteresis characteristic as a piezoelectric element and a characteristic as a tactile sensor (touch sensor, vibration sensor) could be confirmed.

It is expected that MEMS will be used for various technical fields and products in the future. As described above, the micro-electromechanical system manufacture method of the present invention as well as a die and a film used for this manufacture method can eliminate the vacuum process and many manufacture steps and can use a general resin molding (e.g., compressive molding, injection molding, transfer molding) to mass-produce MEMSs having various functions through simple steps, thus significantly reducing the MEMS manufacture cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A method for manufacturing a micro-electromechanical system, comprising:
aligning a film with a die so as to contact with each other, the film having a functional layer and a releasing layer printed thereon, the die configured to mold a structure which comprises a functional layer retention part retaining the functional layer and a frame supporting the functional layer retention part;
curing resin filled between the die and the film; and
separating the film from the die so that the functional layer is released from the releasing layer and transferred on the resin cured in the die, thereby the structure is formed.

2. A method for manufacturing a micro-electromechanical system, comprising:
injecting ultraviolet cure resin into a die for molding a structure which comprises a functional layer retention part retaining a functional layer and a frame supporting the functional layer retention part;
aligning a film with the die into which the ultraviolet cure is injected so as to contact with each other, the film having a functional layer and a releasing layer printed thereon;
emitting ultraviolet light to the ultraviolet cure resin so as to cure the resin; and
separating the film from the die so that the functional layer is released from the releasing layer and transferred on the resin cured in the die, thereby the structure is formed.

3. A method for manufacturing a micro-electromechanical system, comprising:
injecting thermosetting resin into a die for molding a structure which comprises a functional layer retention part retaining a functional layer and a frame supporting the functional layer retention part;
aligning a film with the die into which the ultraviolet cure resin is injected so as to contact with each other, the film having a functional layer and a releasing layer are printed thereon;
heating the die so as to cure the resin; and
separating the film from the die so that the functional layer is released from the releasing layer and transferred on the resin cured in the die, thereby the structure is formed.

4. A method for manufacturing a micro-electromechanical system, comprising:
setting a die with respect to a stationary injection molding die, the die configured to mold a structure which comprises a functional layer retention part retaining a functional layer and a frame supporting the functional layer retention part;
aligning a film with the die so as to contact with each other, the film having a functional layer and a releasing layer formed thereon;
clamping the stationary injection molding die with a movable injection die;
injecting molten thermoplastic resin through the injection opening of the stationary injection molding die so as to fill the thermoplastic resin in the dies for molding the structure;
cooling the thermoplastic resin so as to cure the resin;
separating the movable injection molding die from the stationary injection molding die;
separating the film from the stationary injection molding die so that the functional layer is released from the releasing layer and transferred on the resin cured in the die, thereby the structure is formed; and
ejecting the resin from the stationary injection molding die.

5. The method according to claim 1, wherein the releasing layer is formed of water-repellent resin such as silicone resin.

6. The method according to claim 1, wherein
the releasing layer is formed of resin dissolved in solvent or inorganic matter; and
the film is immersed in the solvent when released from the die.

7. A die used for the method according to claim 1, comprising:
a first concave section that is filled with resin so as to correspond to the functional layer retention part of the micro-electromechanical system,
a first convex section provided at the outer periphery of the first concave section,
a second concave section that is provided at the outer periphery of the first convex section and that uses filled resin to form a frame of the micro-electromechanical system,
a second convex section provided at the outer periphery of the second concave section, and
a third concave section that is provided at the first convex section and that uses filled resin to connect the first concave section to the resin filled in the second concave section.

8. The die according to claim 7, wherein the first convex section and the second convex section have an outer edge and an inner edge having a blade-like shape.

9. The die according to claim 7, wherein the third concave section has a zigzag-like shape.

10. The die according to claim 7, wherein the third concave section is shaped to have a plurality of stripes.

11. A die aggregation, comprising:
the die according to claim 7, the die being arranged in lengthwise and crosswise directions.

12. The die aggregation according to claim 11, wherein
the second convex section is adjusted in height so as to form a thin resin layer; and
the respective micro-electromechanical systems are connected by the thin resin layer and can be ejected from the die aggregation.

13. A film used for the method according to claim 1, comprising: a pattern-coating on the functional layer and the releasing layer coated by a screen printing, a relief printing, or a gravure printing.

14. The film according to claim 13, wherein the functional layer comprises a pattern-coating coated via an intermediate layer.

15. A film used for the method according to claim 1, comprising:
the functional layer formed by etching a semiconductor substrate; and
the releasing layer and an adhesive layer which comprise a pattern-coating coated by a screen printing, a relief printing, or a gravure printing, wherein
the functional layer is adhered to the releasing layer via the adhesive layer.

16. A micro-electromechanical system manufactured by the method according to claim 1, comprising:
the functional layer which is retained by resin filled in the functional layer retention part; wherein
the resin filled in the functional layer retention part is integrally connected to the resin part of the frame supporting the functional layer retention part.

17. The micro-electromechanical system according to claim 16, wherein
a connecting section between the functional layer retention part and the frame is formed in an electrode layer of the functional layer.

18. The micro-electromechanical system according to claim 16, wherein
the connecting section of the frame causes the functional layer retention part to elastically deform at a predetermined stroke to the frame.
